(19) United States
(12) Patent Application Publication
(10) Pub. No.: US 2015/0056447 A1
(43) Pub. Date: Feb. 26, 2015

(54) ENHANCING THE ADHESION OR ATTACHMENT OF CARBON NANOTUBES TO THE SURFACE OF A MATERIAL VIA A CARBON LAYER

(71) Applicants: CENTRE NATIONAL DE LA RECHERCHE SCIENTIQUE - CRS, Paris Cedex 16 (FR); ÉCOLE CENTRALE DE PARIS, Châtenay-malabry (FR)

(72) Inventors: Jinbo Bai, Antony (FR); Youqin Lin, Antony (FR); Anthony Dichiara, Antony (FR)

(21) Appl. No.: 14/370,511

(22) PCT Filed: Jan. 11, 2013
(86) PCT No.: PCT/FR2013/050066

§ 371 Date: Jul. 3, 2014

(30) Foreign Application Priority Data
Jan. 12, 2012 (FR) 1250301

(51) Int. Cl. C23C 16/26; C23C 16/02; C23C 16/448; C01B 31/02

(52) U.S. Cl. CPC C23C 16/26; C01B 31/0253; C23C 16/0209; C23C 16/4486
USPC 428/368; 428/403; 427/249.1; 427/249.4

(57) ABSTRACT

The present invention relates to a method for enhancing the adhesion of CNTs to the surface of a material, including the following steps carried out under an inert gas current or currents optionally mixed with hydrogen: (i) heating the material including CNTs on the surface thereof in a reaction chamber, to a temperature of between 500° and 1,100° C.; (ii) introducing into said chamber a carbon source consisting of acetylene and/or xylene, in the absence of a catalyst; (iii) exposing the heated material to the carbon source for a period of time sufficient to ensure the production of a carbon layer of controlled thickness on the surface of said material and said CNTs covering same, as shown in the figure below; and (iv) optionally recovering the material thus covered after cooling, upon completion of step (iii). The invention likewise relates to hybrid carbon-coated reinforcements and to the uses thereof for preparing structural and functional composite materials or for preparing paints or varnishes and wires.

### TECHNICAL FIELD

The present invention relates to a method for improving the attachment of carbon nanotubes (abbreviated to CNTs) to various reinforcements of particle or fiber type and to the properties of these hybrid reinforcements comprising such CNTs.

This method consists of a deposition of at least one carbon layer, in particular of a carbon nanolayer, by the chemical vapor (abbreviated to CVD) route, on multiscale hybrid reinforcements, such as, for example, particles or fibers, said reinforcements being covered with CNTs. Reference is also made to a graphitization method. This method thus makes it possible to provide better attachment of said CNTs to said reinforcements, on the one hand, and to increase the electrical/thermal conductivity and the mechanical strengths of these reinforcements, on the other hand, as well as to improve the multifunctional properties of the associated composite materials.

In the description below, the references in brackets ([ ]) refer to the list of the references presented at the end of the text.

### STATE OF THE ART

The method for the manufacture of multiscale hydride reinforcements, such as, for example hybrid reinforcements of micrometric size, indeed even of nanometric size, by CVD have already been patented under the reference FR0806869. In particular, a description is given, in the patent FR0806869, of an alternative form of a method for the synthesis of CNTs at the surface of a material for applications which require a particularly strong bond between the CNTs and the reinforcement. This alternative form comprises an additional step in which either a heat treatment, which makes it possible to create nanowelds between the CNTs and the reinforcement, is applied or a deposition of biocompatible conducting polymer is carried out on the material obtained on conclusion of the method for the synthesis of the CNTs.

Nevertheless, it turns out that the attachment of CNTs to particles and fibers by this alternative form is not entirely satisfactory and that rendering the CNTs integral with their support thus remains an issue requiring an appropriate response in order not to form an obstacle to certain applications envisaged. During the implementation of the composites, which consist of a dispersion of hybrid reinforcements in a matrix, and during the use of these composites under stresses of mechanical and/or electrical and/or chemical and/or thermal and/or electromagnetic nature, a thermally and chemically stable, often strong, controlled adhesion is necessary. This adhesion can improve the transmission of the electric current, of the heat flow and of the mechanical stresses between (a) the CNTs, (b) the micrometric reinforcements and (c) the matrix. The CNTs may in addition exhibit a safety problem during (i) their handling operations during the various production steps and (ii) their applications, and also at the time of their end of life. This is because, due to their size of the order of the nanometer, CNTs can represent a danger to the health if they are dispersed in the atmosphere in the free form, that is to say not attached to a support of greater size, such as, for example, a reinforcement of the size of the order of the micrometer. There thus exists a real need to improve the long-term attachment and adhesion of the CNTs on these reinforcements and to thus overcome the disadvantages of the prior art.

The applicant company has discovered a novel method which makes it possible to improve the attachment of CNTs to reinforcements. This method consists in depositing a fine layer of carbon, which furthermore proves to be an excellent electrical and thermal conductor and which has good mechanical strength, on hybrid reinforcements composed of CNTs and of particles and/or fibers. Advantageously, these hybrid reinforcements have a micrometric size.

This method constitutes a method for strengthening the adhesion of CNTs at the surface of a material constituting a hybrid reinforcement, comprising the following steps carried out under a stream of inert gas(es), optionally as a mixture with hydrogen:

(i) heating said hybrid reinforcement, comprising CNTs at its surface, in a reaction chamber at a temperature ranging from 500° C. to 1100° C.,
(ii) introducing, into said chamber, a carbon source consisting of acetylene and/or xylene, in the absence of catalyst;
(iii) exposing said heated hybrid reinforcement to the carbon source for a period of time sufficient to obtain a carbon layer of controlled thickness at the surface of said material and said CNTs covering it, the thickness being controlled according to the application desired;
(iv) recovering, optionally after cooling, said hybrid reinforcement, obtained in conclusion of step (iii), covered with a carbon layer and comprising CNTs sheathed with a carbon layer.

In the context of the invention, the term “CNTs sheathed with a carbon layer” is understood to mean CNTs which are surrounded by a carbon layer, either having the same structure as the CNTs themselves, that is to say that the CNT is surrounded by at least one concentric graphene layer, or having a less graphitized structure for certain specific applications.

This method thus provides a novel technical solution which makes it possible to strengthen and to consolidate the attachment between the CNTs and the reinforcements, while retaining, indeed even while improving, their properties and offers, in addition, the opportunity of using said reinforcements in a secure manner.

Indeed, this strengthening operation contributes to the safety and to the protection of the users and consequently the constraints related to health and safety are greatly reduced thereby. It also makes it possible to prevent possible detachment of the CNTs which may take place during the handling, the use and the transportation of said reinforcements and the application of the materials prepared, for example composite materials.

The method of the deposition of carbon on hybrid reinforcements by CVD in the presence of acetylene and/or xylene as carbon sources makes possible deposition of carbon both on the CNTs and on the reinforcements, in particular particles or fibers.

It results in a high degree of graphitization of the carbon layer deposited according to the conditions of the invention and also good attachment between micrometric reinforcements and CNTs, making possible a significant improvement in the electrical, thermal and/or mechanical properties of the products obtained.

In addition, it can make possible control of the thickness of the carbon deposit and of the weight of carbon deposited on the CNTs and on the reinforcements. As the carbon deposit forms concentric graphite layers around the CNTs, it is possible in this way to adjust their external diameter in a precise and homogeneous fashion.

In fact, in the prior art, there exist two possible routes for adjusting the external diameter of CNTs.

The first route is a reaction by CVD with catalysts of controlled size predeposited on substrates. However, this route results in a high production cost, makes possible only a low production capacity, employs a method in several steps with different or expensive techniques and comprises numerous defects for large diameters. The second route consists of a reaction by aerosol-assisted CVD, the catalysts then being generated in situ in the gas. This route exhibits a low production cost and makes possible a high production capacity but the diameter is very difficult to control. Indeed the distribution in diameter of the CNTs synthesized by aerosol-assisted CVD becomes increasingly multimodal as the diameter of the CNTs increases.

The length of the CNTs is for its part determined during their manufacture by the growth time under the influence of the temperature and the concentration of the sources of carbon and of catalyst.

The applicant has now also found a method which makes it possible to control the external diameter of the CNTs in a precise and homogeneous fashion. This method for controlled enhancement of the diameter of the CNTs additionally comprises the steps of the method for strengthening the adhesion of CNTs at the surface of a material constituting a hybrid reinforcement. Furthermore, this method has the advantage of using the same equipment as for the growth of said CNTs, thus bringing about easy, rapid and efficient methoding. More particularly, this method can take place, for example, directly subsequent to the method for the synthesis of the hybrid reinforcements, without interruption and without any modification to the equipment used. This method comprises the application of an aerosol-assisted CVD with catalysts generated in situ.

This method comprises, prior to the steps of the method for strengthening the adhesion of CNTs at the surface of a material constituting a hybrid reinforcement, a step of growth of CNTs on said reinforcements by CVD in the presence of catalyst and then a step of deactivation of said catalyst by a heat treatment under H₂.

This method advantageously takes place in 3 steps, which can optionally be carried out continuously, and makes it possible to obtain the advantages of low cost and of high production capacity while avoiding the disadvantages of the prior art.

The first step can thus consist in bringing about the growth, according to a “standard” growth by aerosol-assisted CVD, of CNTs of desired length and with small diameters of between 3 and 20 nm, in order to obtain a distribution in diameter of the CNTs which is uniform and monodispersed.

The second step can consist of a deactivation of a catalyst present subsequent to the “standard” growth mentioned above by a heat treatment under H₂, so that the CNTs cannot continue to grow in length during the following step.

The third step, resuming the method according to the invention, consists in implementing a CVD method but without the contribution of catalyst, the pyrolytic carbon formed during this method by the carbon sources introduced then being deposited around these CNTs in a concentric manner, like a sheath, in order to achieve the desired external diameter while retaining unchanged the internal diameter and the length of the CNTs. The various characterization methods (Raman, HRTEM, SEM, diffraction) have shown a structure with good graphitization of the carbon deposited, similar to that of the original CNTs.

Thus, the method for strengthening the adhesion of CNTs at the surface of a material constituting a hybrid reinforcement, as described below, can advantageously prove to be a method which makes possible the controlled enhancement of the CNT diameter. Indeed it is possible, according to the operating conditions employed, to control the final diameter of the CNTs and thus to manufacture uniform CNTs with a very precise diameter.

The method for controlled enhancement of the CNT diameter, which can make possible an enhancement in the diameter which can reach upto an additional 200 nm per pitch of 0.34 nm, additionally comprises the steps of the method for strengthening the adhesion of CNTs at the surface of a material constituting a hybrid reinforcement. This method can comprise, prior to the steps of the method for strengthening the adhesion of CNTs at the surface of a material constituting a hybrid reinforcement, a step of growth of CNTs on said reinforcements by CVD in the presence of catalyst, such as a metallocene, such as ferrocene (Fe(C₅H₅)₂), and then optionally a step of deactivation of said catalyst by a treatment under H₂.

Finally, the method according to the invention, used either to strengthen the adhesion or the attachment of CNTs at the surface of the material, thus constituting a hybrid reinforcement, and/or or to adjust or control the diameter of the CNTs, promotes the reduction of dangerous products, such as benzene and toluene, decomposition products from xylene when the two carbon sources, acetylene and xylene, are used simultaneously.

In the context of the present invention, the term “composite material” is understood to mean a material comprising at least two components: one is “the matrix”, which provides for the cohesion of the composite, and the other is “the reinforcement”, which provides the composite with the advantageous physical and mechanical qualities.

In the context of the present invention, the term “reinforcement” is understood to mean a material which can be used to provide, for example, the composite materials with physical and mechanical properties, such as, for example, (i) tensile, torsional, flexural and compressive strength, (ii) stiffness and lifetime, (iii) lightening of the density, (iv) corrosion resistance, (v) electrical and thermal conductivity and (vi) shielding of electromagnetic waves.

In the context of the present invention, the term “hybrid reinforcement” is understood to mean a reinforcement, as defined above, which can be provided in the form of a conventional reinforcement, at the surface of which CNTs have been synthesized, for example chosen from the group comprising:
carbon, glass, alumina, silicon carbide (SiC) or rock fibers;
ceramic materials chosen from the group comprising particles and/or fibers of silicon nitride (Si₃N₄), boron carbide (B₄C), silicon carbide (SiC), titanium carbide (TiC), cordierite (Al₃Mg₂AlSi₅O₁₈), mullite (Al₆Si₂O₁₃), aluminum nitride (AlN), boron nitride (BN), alumina (Al₂O₃), aluminum boride (AlB₂), magnesium oxide (MgO), zinc oxide (ZnO), magnetic iron oxide (Fe₃O₄), zirconia (Zr₂O), silica (SiO₂), fumed silica, CaO, La₂CuO₄, La₂NiO₄, La₂SrCuO₄, Nd₂CuO₄, TiO₂, Y₂O₃, and aluminum silicates (clays).

In the context of the present invention, the term “nanotube” is understood to mean a tubular carbon-based structure which has a diameter of between 0.5 and 100 nm. These compounds belong to the family referred to as of “nanostructured materials”, which exhibit at least one characteristic dimension of the order of the nanometer.

The method which is the subject matter of the present invention is the same whether it concerns covering hybrid reinforcements composed (i) of fibers and of CNTs and/or (ii) of particles and of CNTs.

The method of the invention exhibits the advantage of being suitable for all types of material, whatever its structure: short, long or continuous fibers, or particles. Within the meaning of the invention, a fiber is said to be “long or continuous” when its length is equal to or greater than 10 cm and a fiber is said to be “short” when its length is less than 10 cm.

### Detailed Technical Description of the Invention

It is thus an aim of the present invention to provide a method for strengthening the adhesion of CNTs at the surface of a material constituting a hybrid reinforcement, comprising the following steps carried out under a stream of inert gas(es), optionally as a mixture with hydrogen:

(i) heating said hybrid reinforcement, comprising CNTs at its surface, in a reaction chamber at a temperature ranging from 500° C. to 1100° C., advantageously between 700° C. and 900° C. and more advantageously still between 750° C. and 850° C.;
(ii) introducing, into said chamber, a carbon source consisting of acetylene and/or xylene, in the absence of catalyst;
(iii) exposing said hybrid reinforcement to the carbon source, heated for a period of time sufficient to obtain a carbon layer of controlled thickness at the surface of said material and said CNTs covering it, the thickness being controlled according to the application desired, the thickness of the carbon layer formed advantageously being between 0.002 and 5 μm and more advantageously between 2 and 250 nm;
(iv) recovering, optionally after cooling, said hybrid reinforcement, obtained in conclusion of step (iii), covered with a carbon layer and comprising CNTs sheathed with a carbon layer.

According to one embodiment, said method for strengthening the adhesion of CNTs at the surface of a material or reinforcement can be a continuous method. The term “continuous method” is understood to mean a method in which the introduction of the materials or hybrid reinforcements, at the surface of which the carbon layer is deposited, does not require shutting down the equipment or interrupting production.

Depending on the desired thickness of the carbon layer, the hybrid reinforcement can be exposed to the carbon source for a period of time of 1 to 60 minutes in step (iii). This period of time can be from 1 to 30 minutes or also from 5 to 15 minutes.

A person skilled in the art will know how to adjust this period of time according to, on the one hand, the desired thickness of the carbon layer, the targeted application of the hybrid reinforcements and the risk of decomposition of the material making up said reinforcements during the method according to the invention.

In addition, in step (iv), the hybrid reinforcement covered with a carbon layer obtained on conclusion of step (iii) can be recovered, optionally after a step of cooling to a temperature of between 15 and 150° C. On conclusion of step (iv), the hybrid reinforcement covered with a carbon deposit can be used as is in the various applications envisaged.

The principle of the method for the deposition of carbon on hybrid reinforcements is based on a mechanism which consists in carrying out the deposition of carbon on hybrid reinforcements preferably composed of particles and/or fibers advantageously by the CVD method in a reactor placed in a furnace heated between 500 and 1100° C., fed with acetylene, continuously, and/or with xylene, as carbon source(s).

The reaction chamber can be any device provided with at least one furnace and which makes possible the simultaneous and controlled injection of gaseous carbon source and/or of liquid carbon source. The device is advantageously provided with at least one system for circulation of gases and with at least one gas and/or liquid flow meter, according to the carbon source used, which makes it possible to accurately measure and control the flow rates of the gases and/or liquids. An example of a device is represented in FIG. 1.

The liquid xylene stream can be controlled by a mechanical syringe and/or a commercial liquid mass flowmeter. With regard to the gaseous flow rate of acetylene, of inert gas and optionally mixed with hydrogen, it can be controlled by said commercial digital mass flowmeters.

The system used for the introduction of the liquid can be any system which allows it to be injected, for example an atomizer, a vaporizer, a nebulizer or an air spray.

According to a particularly advantageous embodiment of the method, in step (ii), the liquid is introduced into the reaction chamber in the form of microdroplets via a spray at a rate which can range from 0 to 30 ml/hour.

According to one embodiment of the method, in step (ii), the acetylene is introduced into the reaction chamber with a linear velocity of between 5.0×10⁻⁶ and 1.0×10⁻¹ m/s and/or the xylene is introduced into the reaction chamber at a flow rate varying between 0.1 and 0.7 ml/min.

The term “linear velocity” is understood to mean the distance traveled by the acetylene in 1 second. The linear velocity is determined as a function of the flow rate of the acetylene and of the volume of the reaction chamber. For example, for a reactor with an internal diameter of 45 mm, a gas flow rate of 1 l/min corresponds to a linear velocity of 0.0095 m/s. This is true for all the gases used in the context of the present invention.

Steps (i) to (iv) can be carried out under a stream of inert gas(es), optionally in a mixture with hydrogen, with a hydrogen/inert gas(es) ratio ranging from 0/100 to 50/50, for example from 10/100 to 40/60. The inert gas can be chosen from the group comprising helium, neon, argon, nitrogen and krypton.

Thus, in step (ii), the acetylene can be introduced into the reaction chamber in the gas form in an amount of greater than 0 and ranging up to 20% by volume of the total gas present in said chamber. It can also be introduced, for example, in an amount ranging from 0.1% to 10% by volume of the total gas.

The use of the preceding arrangements makes it possible to control the deposition and thus the thickness of the carbon layer covering both reinforcements and CNTs.

According to one embodiment of the method, CNT photographs of which are visible in FIG. 22, the reinforcement in said hybrid reinforcement is provided in the form of short or long fibers, with a diameter of 1 to 100 μm, in particular of fibers with a diameter of 4 to 50 μm, or of particles with a diameter of 0.1 to 100 μm.

The material constituting the reinforcement to be treated is chosen from those capable of withstanding the temperature of the method according to the conditions of the invention.

This material can be chosen from the group comprising:
carbon, glass, alumina, silicon carbide (SiC) or rock fibers;
ceramic materials chosen from the group comprising particles and/or fibers of silicon nitride (Si₃N₄), boron carbide (B₄C), silicon carbide (SiC), titanium carbide (TiC), cordierite (Al₃Mg₂AlSi₅O₁₈), mullite (Al₆Si₂O₁₃), aluminum nitride (AlN), boron nitride (BN), alumina (Al₂O₃), aluminum boride (AlB₂), magnesium oxide (MgO), zinc oxide (ZnO), magnetic iron oxide (Fe₃O₄), zirconia (Zr₂O), silica (SiO₂), fumed silica, CaO, La₂CuO₄, La₂NiO₄, La₂SrCuO₄, Nd₂CuO₄, TiO₂, Y₂O₃, and aluminum silicates (clays).

The performance of this innovative method depends on the control of the morphology and of the structure of the carbon layer deposited. Different chemical precursors, such as acetylene and xylene, are employed with diverse physical parameters, such as the temperature and the time, so as to optimize the method of the deposition of carbon on the hybrid reinforcements as a function of the applications desired.

It is possible to apply a high degree of control of the thickness of deposition of carbon and of its weight by manipulation of the deposition parameters. The high degree of control of the thickness of the layer of carbon deposited, of the weight of carbon deposited on the hybrid reinforcements and also the degree of graphitization can be adjusted as a function of the deposition time and of the temperature of the method. The deposition time can linearly increase the amount of deposit, that is to say the thickness of the carbon layer, whereas the deposition temperature nonlinearly influences the amount of carbon deposited, and also its structure.

The method according to the invention makes possible the deposition of carbon on the surface of the hybrid reinforcements, including on the surface of the CNTs. The deposition time has little influence on the quality of the graphitization, that is to say the quality of the structure of the deposited carbon, whereas a high deposition temperature is favorable to better graphitization, that is to say is favorable to the formation of a graphitic carbon-based structure exhibiting few defects.

The deposition of carbon on the hybrid reinforcements improves the attachment between the CNTs and the micrometric reinforcements, such as, for example, micrometric particles and fibers, and the CNTs. It has been proved, by ultrasound tearing-off tests, that the hybrid reinforcements, after the deposition of carbon, can better withstand impacts, stresses and/or shaking and thus detachment, compared with the original hybrid reinforcements. The dispersion of the CNTs in air is thus effectively reduced.

In addition, the electrical properties of the hybrid reinforcements are seen to be improved thereby. The deposition of carbon on insulating micrometric reinforcements of hybrid reinforcements makes possible better electrical/thermal conduction between the CNTs, whereas the deposition of carbon on the CNTs can, according to its degree of graphitization, render them electrically less conductive than the original CNTs. In the hybrid reinforcements with a low CNT density, electrical conductivity of the hybrid reinforcements may be enhanced due to the deposition of carbon on the surface of the micrometric reinforcements.

It is possible to carry out the method with acetylene as sole carbon source, according to a first alternative form, or with a mixture of acetylene and liquid hydrocarbon, such as xylene, as carbon sources, according to a second alternative form.

In the case where acetylene alone is used as sole carbon source, the carbon layer deposited is finer and the method according to the invention is stable while the deposition time is longer compared with the method using acetylene and xylene simultaneously.

The method according to the invention involving a mixture of acetylene and xylene as carbon source is thus particularly advantageous and makes possible a satisfactory treatment of the hybrid reinforcements, while promoting the reduction of dangerous products, such as benzene and toluene, resulting from the decomposition of the xylene.

This novel method is of industrial interest:

It makes possible a deposition of a homogeneous carbon layer over the surface of hybrid reinforcements composed, for example, of micrometric particles, of nanotubes or nanowires of carbon or other nature. Practically all types of reinforcements can be envisaged.

It makes it possible to obtain the deposition of a carbon layer with a structure which can vary according to the temperature conditions applied (amorphous carbon or graphite).

It also makes possible a high degree of control of the thickness or of the quality of carbon deposited on the hybrid reinforcements and consequently a high degree of control over the diameter of the CNTs in the case of a concentric graphite deposit around the CNTs.

Finally, it makes it possible to adjust the electrical/thermal conductivity and the mechanical properties of the hybrid reinforcements according to the morphology of the reinforcements and the practical applications envisaged.

Another subject matter of the invention is a hybrid reinforcement, that is to say a reinforcement or material covered with CNTs, capable of being obtained by a method as defined above, it being known that said reinforcement and said CNTs are covered with a carbon layer. A system, reinforcement and CNT, covered with a homogeneous carbon layer, is thus obtained.

According to one embodiment, said hybrid reinforcement has an increase in weight of between 0% and 150%, with respect to the weight of the original material.

The hybrid reinforcement according to the invention is covered with a carbon layer and comprises CNTs sheathed with said carbon layer.

The hybrid reinforcement according to the invention is provided in the form of a reinforcement covered with CNTs, said reinforcement and said CNTs being covered with a carbon layer of controlled thickness, the thickness being controlled as a function of the application desired, the thickness of the carbon layer formed advantageously being between 0.002 and 5 μm, more advantageously still between 2 and 250 nm.

The material constituting the reinforcement is chosen from those capable of withstanding a temperature of at least 500° C., indeed even a temperature which can reach 1100° C. It can be chosen from the group comprising:
carbon, glass, alumina, silicon carbide (SiC) or rock fibers;
ceramic materials chosen from the group comprising particles and/or fibers of silicon nitride (Si₃N₄), boron carbide (B₄C), silicon carbide (SiC), titanium carbide (TiC), cordierite (Al₃Mg₂AlSi₅O₁₈), mullite (Al₆Si₂O₁₃), aluminum nitride (AlN), boron nitride (BN), alumina (Al₂O₃), aluminum boride (AlB₂), magnesium oxide (MgO), zinc oxide (ZnO), magnetic iron oxide (Fe₃O₄), zirconia (Zr₂O), silica (SiO₂), fumed silica, CaO, La₂CuO₄, La₂NiO₄, La₂SrCuO₄, Nd₂CuO₄, TiO₂, Y₂O₃, and aluminum silicates (clays).

The reinforcement in said hybrid reinforcement can be provided in the form of short or long fibers as defined above, with a diameter of 1 to 100 μm, in particular of fibers with a diameter of 4 to 50 μm, or of particles with a diameter of 0.1 to 100 μm.

Finally, the invention also relates to the use of said hybrid reinforcement in the preparation of structural and functional composite materials or in the preparation of paints or varnishes or also threads or strips.

These uses are particularly promoted by the advantages conferred by the product obtained in conclusion of the method and which are directly related to the reaction conditions. The advantages of the vapor phase deposition, without chemical catalyst, combining two carbon source entities: acetylene, which is a gas, and xylene, which is a liquid, can be summarized as follows:
The deposition of a thin carbon layer on hybrid reinforcements composed of micrometric particles and of CNTs makes it possible to better attach said CNTs to the surface of said micrometric particles and/or fibers.
The carbon layer deposited during the method according to the invention is electrically and thermally conducting and thus does not damage the electrical/thermal conductivity of the CNTs.
The deposition by CVD under inert gas at high temperature has the advantage of making possible a higher level of graphitization and a structure of the carbon deposit which is more homogeneous and of better quality compared with the structures obtained by other low temperature techniques for the deposition of carbon, such as pulsed laser [1], plasma [2], electrodeposition [3], and the like.
The use of conjugated molecules as carbon source (acetylene, xylene) can result in a higher concentration of sp² bonds in the carbon deposit than other nonconjugated carbon sources at low temperature. It has thus been shown that the carbon deposit derived from acetylene has a higher crystalline order, corresponding to a higher degree of graphitization, and fewer grain boundaries than the alkyls [4]. This helps enhancing the conductivity of the carbon deposit layer.
The simultaneous use of acetylene with another hydrocarbon, such as xylene, can make possible control of the degree of carbon deposition within a wide range of parameters over the hybrid reinforcements by adjusting the deposition temperature. It is thus possible to deposit the carbon at a lower temperature, if necessary with an acetylene/xylene mixture (550° C. with xylene instead of 750° C. without xylene). In this case, the degree of graphitization of the carbon deposit will be lower but the carbon deposit can then be produced at the surface of materials which are thermally less resistant. The use of the gaseous carbon source makes possible, in addition, a more homogeneous deposition of carbon and often less rapid deposition over the hybrid reinforcements than use of a liquid carbon source alone.
Finally, the concentration of benzene and toluene during the deposition method (one of the pyrolytic products from xylene) can be lowered by simultaneously using xylene and acetylene as carbon sources of the method according to the invention.

Carbon as deposition material in addition makes it possible to provide and to enhance (i) the electrical/thermal conductivity and the mechanical properties of these reinforcements and also of the associated composites, as is shown by the electrical conductivity and mechanical properties tests. Likewise, in high-temperature applications and/or in a corrosive medium, the choice of carbon proves to be particularly advantageous for its thermal and chemical stability.

Furthermore, the subject matter of the present invention has the additional advantage of providing a method for strengthening the attachment of the CNTs to hybrid reinforcements using the same equipment as for the growth of said CNTs on said reinforcements, thus bringing about easy, rapid and efficient methoding. More particularly, this method, which can take place directly subsequent to the method for the synthesis of the hybrid reinforcements without interruption and without any modification to the equipment used, makes it possible to control both the thickness of the carbon layer deposited on the hybrid reinforcements and in particular the diameter of the CNTs, thus improving adhesion of the CNTs on the micrometric reinforcements, testified to by tests of resistance to ultrasound.

Other advantages may also become apparent to a person skilled in the art on reading the examples below, illustrated by the appended figures, given by way of illustration.

### BRIEF DESCRIPTION OF THE FIGURES

FIG. 1 represents the diagram of an arrangement used for the method for strengthening the adhesion of CNTs at the surface of a material by CVD.

FIGS. 2, 3, 4, 5, 6 and 7 are images obtained by a scanning electron microscope (SEM) of a hybrid reinforcement composed of CNTs and of a microparticle, bringing out the morphological difference with a carbon deposit layer of variable thickness on the surface of a microparticle and of CNTs for FIGS. 4, 5, 6 and 7 or without a carbon deposit layer on the surface of a microparticle and of CNTs for FIGS. 2 and 3.

FIGS. 4 and 5 show hybrid reinforcements according to the invention with a carbon deposit on the surface of said reinforcements obtained by the CVD method.

FIGS. 6 and 7 show the details of the deposit on the surface of a microparticle and of a CNT. FIG. 6 shows a magnification of a CNT, appearing in light gray, shaded by a darker carbon layer and FIG. 7 shows a homogeneous deposit layer, appearing in dark gray, on the surface of the microparticle, which appears in black.

FIG. 8 shows the result of the spectroscopic analysis of the loss of the electron energy at the surface of a particle after the carbon deposition, confirming the presence of a carbon layer of nanometric thickness.

FIG. 9 represents the change in the weight of carbon deposited on a hybrid reinforcement as a function of the carbon deposition time.

FIG. 10 represents the change in the weight of carbon deposited on a nanotube alone as a function of the carbon deposition time.

FIG. 11 shows the linear increase in the CNT diameter as a function of the carbon deposition time.

FIGS. 12A and 12B show the influence of the synthesis parameters.

FIG. 12A shows the influence of the deposition time and FIG. 12B shows the influence of the deposition temperature on the ratio of the intensity of the D band to the intensity of the G band (ID/IG) obtained by Raman spectroscopy, which is conventionally used to quantitatively evaluate the structural quality of CNTs (also known as degree of graphitization). The deposition time has little influence on the ID/IG ratio of the carbon deposit on the surface of the micrometric particles. However, a high temperature for deposition of carbon on the CNTs promotes a lower ID/IG ratio than that preceding, which suggests the presence of few structural defects and thus of a high purity of the carbon layer deposited on the CNTs [8]. The method for the deposition of a carbon nanolayer thus does not enhance the amount of defects of the CNTs. This method can thus also be used in order to homogeneously and precisely enhance a posteriori the external diameter of the CNTs without modifying the nature of the latter.

FIGS. 13-18 show the effect of the attachment of the CNTs by carbon deposition on the surface of hybrid reinforcements. FIGS. 13 and 14 constitute images obtained by SEM showing the detachment of the CNTs from hybrid reinforcements, without the carbon deposit, after respectively 1 minute and 5 minutes of low-power ultrasound. FIGS. 15 and 16 constitute images obtained by SEM showing, under the same operating conditions, that is to say after respectively 1 minute and 5 minutes of low-power ultrasound, that the CNTs covered with a carbon layer remain welded to the reinforcements covered with carbon, on which they depend. FIGS. 17 and 18 constitute images obtained by SEM showing that, even after 30 minutes of exposure to maximum-power ultrasound, the morphology of the hybrid reinforcements covered with a carbon layer is retained, thus demonstrating that the deposition of a carbon layer on the hybrid reinforcements helps to achieve better attachment of the CNTs to the surface of the micrometric particles.

FIG. 19 shows the comparison of the electrical conductivity of hybrid reinforcements before and after carbon deposition, demonstrating the positive influence of the carbon deposition on the electrical properties of the hybrid reinforcements.

FIGS. 20 and 21 are images obtained by SEM showing hybrid reinforcements covered with a carbon layer. In FIG. 20, the carbon deposition layer is produced with a method using acetylene. A thin carbon deposition layer is observed. In FIG. 21, the carbon deposition layer on the hybrid reinforcement is obtained with a method using a mixture of xylene and acetylene. The thickness of the carbon deposition layer is satisfactory for attaching CNTs to the surface of the reinforcements.

FIG. 22 combines images obtained by SEM showing (i) a bare carbon fiber (left-hand image), then showing (ii) the same carbon fiber covered with CNTs, also known as hybrid fiber, after a growth of said CNTs by catalytic CVD (middle image), and, finally, showing (iii) said hybrid fiber covered with a fine carbon layer (top-right-hand image) or with a thick carbon layer (bottom-right-hand image) in accordance with the method of the invention.

FIGS. 23A, 23B and 23C represent the stress/strain curves (i) of resin for FIG. 23A, (ii) of composites comprising 0.5% by weight of hybrid reinforcements (hybrid Al₂O₃ particles) not in accordance with the invention for FIG. 23B and of composites comprising 0.5% by weight of hybrid reinforcements (hybrid Al₂O₃ particles) coated with a carbon nanolayer in accordance with the invention for FIG. 23C.

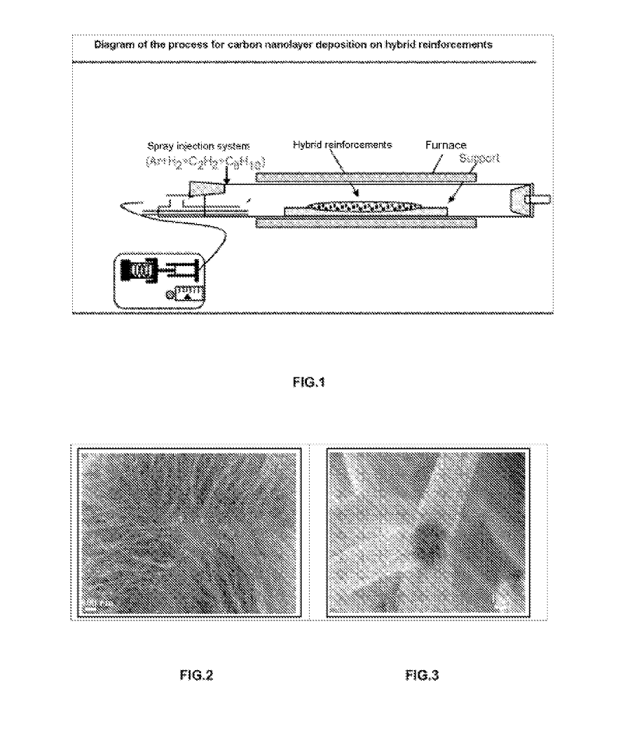

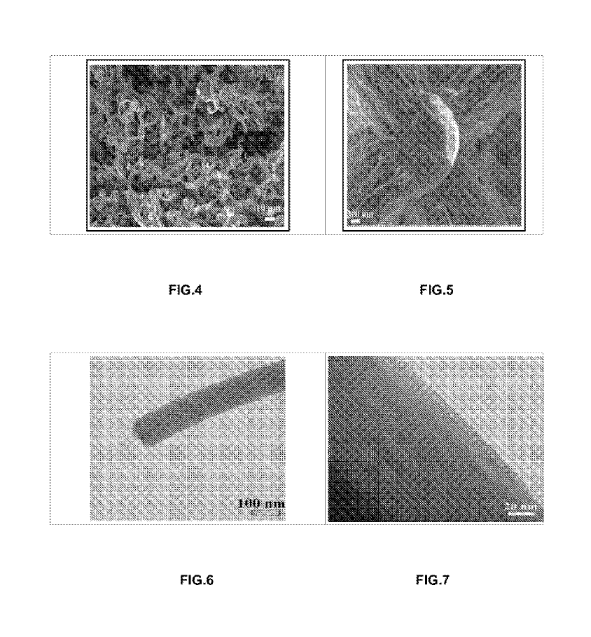

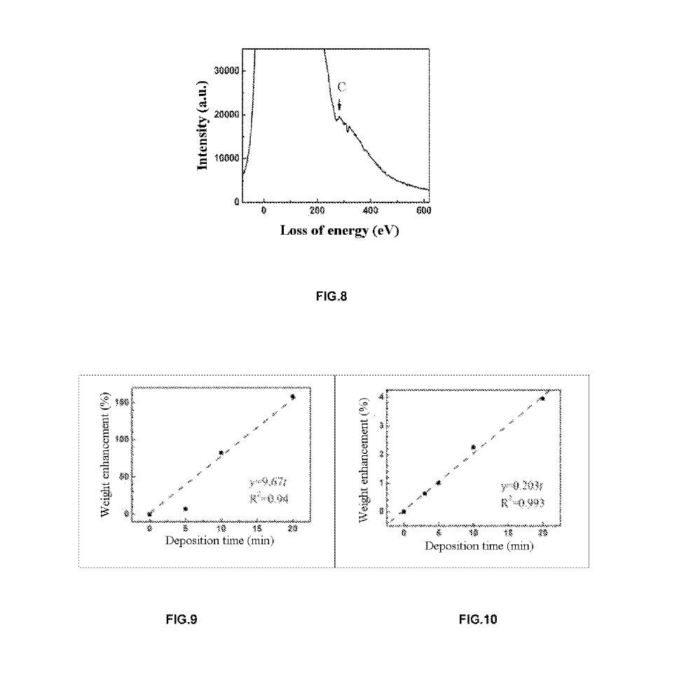

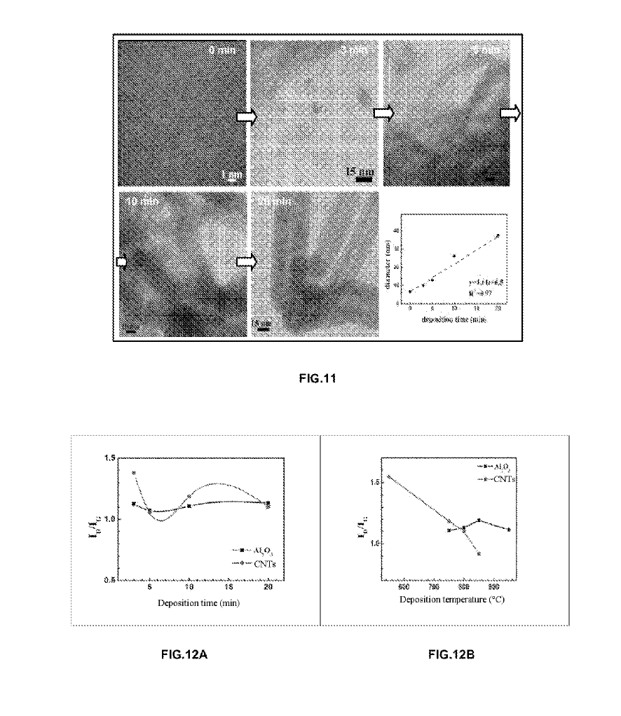

### EXAMPLES

### Example 1

The deposition of a carbon nanolayer is carried out on “long or continuous” carbon fibers with a length of 20 cm grafted with carbon nanotubes, the synthesis of which is described in the patent FR0806869. The carbon deposition is obtained in the same CVD reactor as that described above and represented in FIG. 1 and can optionally be carried out dynamically for a continuous treatment of the various materials.

The thickness, the morphology and the structural properties of the carbon layer deposited are controlled by finely adjusting the parameters of the method according to the invention (temperature, time, gas flow rate, and the like) according to the following conditions:

| Parameters | Fine C nanolayer | Thick C nanolayer |
|---|---|---|
| Temperature (° C.) | 850 | 850 |
| Carbon source(s) | C₈H₁₀ 10 ml/h | C₂H₂ 0.05 l/min + |
| | | C₈H₁₀ 10 ml/h |
| Time (min) | 15 min | 15 min |
| Carrier gases | Ar 0.8 + H₂ 0.2 | Ar 0.8 + H₂ 0.2 |
| (l/min) | | |

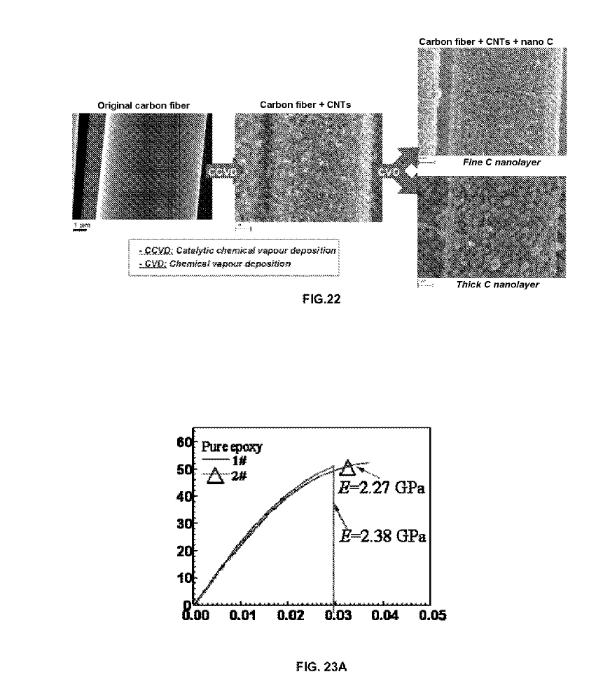

The carbon fibers are photographed by electron microscopy at different steps of the method for the manufacture of the hybrid reinforcements according to the invention and are visible in FIG. 22.

### Example 2

Alumina particles with a diameter of between 1 and 5 μm covered with CNTs, referred to as original hybrid reinforcement, are placed in a furnace as represented in FIG. 1. The method according to the invention is then implemented with the following conditions:

Temperature of the furnace: 850° C.,

Deposition time: 20 min,

Inert gas: Ar: 0.8 l/min; H₂: 0.2 l/min,

Source of carbons:
C₂H₂, injected at a rate of 0.05 l/min
Xylene, injected at a rate of 10 ml/h

On completion of this method, a carbon nanolayer has been deposited on the alumina particle covered with CNTs hybrid structure in order to further attach the CNTs to the alumina particles.

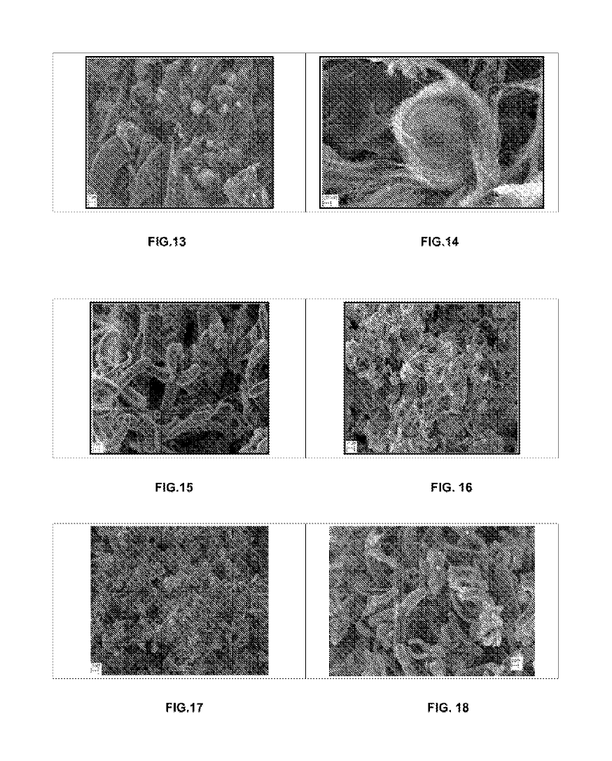

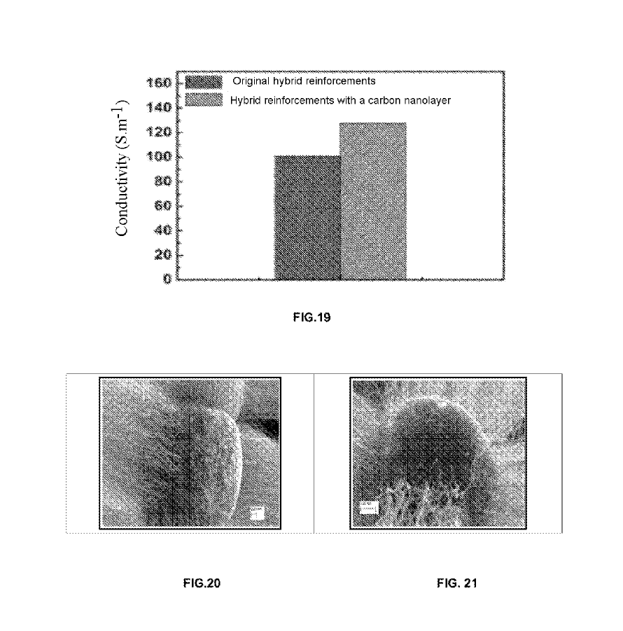

Tearing-off tests carried out with ultrasound testified to a significant improvement in the adhesion of the CNTs to the alumina particles, as is shown in FIGS. 13 to 18.

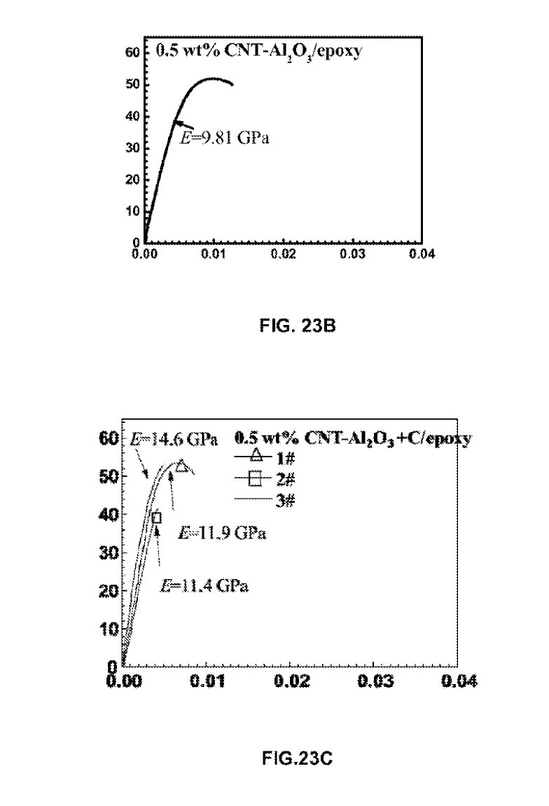

On comparing the stress/strain curve (i) of an epoxy resin (Resoltech® 1080S and 1084) of FIG. 23A, (ii) the stress/strain curve of a composite, the matrix of which is this same epoxy resin mixed with 0.5% by weight of original hybrid reinforcements (CNTs on Al₂O₃ microparticles), of FIG. 23B and (iii) the stress/strain curve of a composite, the matrix of which is this same epoxy resin mixed with 0.5% by weight of hybrid reinforcements (CNTs on Al₂O₃ microparticles) coated with a carbon nanolayer, which are in accordance with the invention, of FIG. 23C, it is found that the modulus has been multiplied by 4 or 6 respectively.

### REFERENCES

1. K. Honglertkongsakul, P. W. May and B. Paosawatyanyong, Electrical and optical properties of diamond-like carbon films deposited by pulsed laser ablation, Diamond and Related Materials, 2010, 19 (7-9), pp. 999-1002.
2. S. Zeb et al., Deposition of Diamond-like Carbon Films Using Graphite Sputtering in Neon Dense Plasma, Plasma Chemistry and Plasma Methoding, 2007, 27 (2), pp. 127-139.
3. T. M. Manhabosco, and I. L. Muller, Electrodeposition of diamond-like carbon (DLC) films on Ti, Applied Surface Science, 2009, 255 (7), pp. 4082-4086.
4. C. A. Taylor, and W. K. S. Chiu, Characterization of CVD carbon films for hermetic optical fiber coatings, Surface & Coatings Technology, 2003, 168 (1), pp. 1-11.
5. S. S. Mahajan et al., Monitoring structural defects and crystallinity of carbon nanotubes in thin films, Pramana-Journal of Physics, 2010, 74 (3), pp. 447-455.

1. Method for strengthening the adhesion of carbon nanotubes at the surface of a material constituting a hybrid reinforcement, comprising the following steps carried out under a stream of inert gas(es), optionally as a mixture with hydrogen:
(i) heating said hybrid reinforcement, comprising CNTs at its surface, in a reaction chamber at a temperature ranging from 500° C. to 1100° C.;
(ii) introducing, into said chamber, a carbon source consisting of acetylene and/or xylene, in the absence of catalyst;
(iii) exposing said hybrid reinforcement to the carbon source, heated for a period of time sufficient to obtain a carbon layer of controlled thickness at the surface of said material and said CNTs covering it;
(iv) recovering, optionally after cooling, said reinforcement, obtained in conclusion of step (iii), covered with a carbon layer and comprising CNTs sheathed with a carbon layer.

2. Method according to claim 1, in which the reinforcement in said hybrid reinforcement is provided in the form of short or long fibers with a diameter from 1 to 100 μm, or of particles with a diameter from 0.1 to 100 μm.

3. Method according to either one of claim 1, in which the material used as reinforcement comprises at least one of:
carbon, glass, alumina, silicon carbide (SiC) or rock fibers;
ceramic materials chosen from the group comprising particles and/or fibers of silicon nitride (Si₃N₄), boron carbide (B₄C), silicon carbide (SiC), titanium carbide (TIC), cordierite (Al₃Mg₂AlSi₅O₁₈), mullite (Al₆Si₂O₁₃), aluminum nitride (AlN), boron nitride (BN), alumina (Al₂O₃), aluminum boride (AlB₂), magnesium oxide (MgO), zinc oxide (ZnO), magnetic iron oxide (Fe₃O₄), zirconia (Zr₂O), silica (SiO₂), fumed silica, CaO, La₂CuO₄, La₂NiO₄, La₂SrCuO₄, Nd₂CuO₄, TiO₂, Y₂O₃, and aluminum silicates (clays).

4. Method according to claim 1, in which, in step (i), the material is heated to a temperature ranging from 700° C. to 900° C.

5. Method according to claim 1, in which, in step (ii), the acetylene is introduced into the reaction chamber in the gas form in an amount greater than 0 and ranging up to 20% by volume of the total gas present in said chamber.

6. Method according to claim 1, in which, in step (ii), the xylene is introduced into the reaction chamber in the form of microdroplets via a spray.

7. Method according to claim 1, in which, in step (ii), the acetylene is introduced into the reaction chamber with a linear velocity of 5.0×10⁻⁶ to 1.0×10⁻¹ m/s and/or in which, in step (ii), the xylene is introduced into the reaction chamber at a flow rate varying between 0.1 and 0.7 ml/min.

8. Method according to claim 1, in which, in step (iii), said hybrid reinforcement is exposed to the carbon source for a period of time of 1 to 60 minutes, depending on the desired thickness of the carbon layer.

9. Method according to claim 1, in which the method for strengthening the adhesion of CNTs at the surface of a material is a continuous method.

10. Method according to claim 1, in which, in step (iv), said hybrid reinforcement covered with a carbon layer, obtained on conclusion of step (iii), is optionally recovered after a step of cooling to a temperature of between 15 and 150° C.

11. Method according to claim 1 in which steps (i) to (iv) are carried out under a stream of inert gas(es), optionally in a mixture with hydrogen, with a hydrogen/inert gas(es) ratio ranging from 0/100 to 50/50.

12. Method according to claim 1, in which the thickness of the carbon layer is between 0.002 and 5 μm, advantageously between 2 and 250 nm.

13. Hybrid reinforcement capable of being obtained by a method according to claim 1, said hybrid reinforcement being provided in the form (i) of a reinforcement comprising, at its surface, (ii) CNTs, said reinforcement and said CNTs being covered with a carbon layer.

14. Reinforcement according to claim 13, having an increase in weight of between 0% and 150%, with respect to the weight of the original material.

15. Reinforcement according to claim 13, configured for preparation of structural and functional composite materials.

16. Reinforcement according to claim 13, configured for preparation of paints or varnishes, threads or strips.

17. Method for the controlled enhancement of the diameter of CNTs additionally comprising the steps of the method as defined according to claim 1.

18. Method according to claim 17, further comprising a step of growth of CNTs on said reinforcements by CVD in the presence of catalyst and then a step of deactivation of said catalyst by a heat treatment under H₂.
